(19) United States
(12) Patent Application Publication
(10) Pub. No.: US 2021/0175458 A1
(43) Pub. Date: Jun. 10, 2021

(54) ORGANIC LIGHT EMITTING DEVICE AND METHOD OF MANUFACTURING THE SAME, DISPLAY APPARATUS

(71) Applicant: BOE TECHNOLOGY GROUP CO., LTD., Beijing (CN)

(72) Inventors: Juanjuan You, Beijing (CN); Chunjing Hu, Beijing (CN)

(21) Appl. No.: 16/811,284

(22) Filed: Mar. 6, 2020

(30) Foreign Application Priority Data
Dec. 4, 2019 (CN) 201911226107.7

(51) Int. Cl. H01L 51/52; H01L 51/56; H01L 27/32

(52) U.S. Cl. CPC H01L 51/5203; H01L 27/3244; H01L 51/56

(57) ABSTRACT

The present disclosure provides an organic light emitting device, a method of manufacturing the same, and a display apparatus. The organic light emitting device includes: a first electrode; a light emitting layer located on a side of the first electrode, a thickness of the light emitting layer being greater than 40 nm, the light emitting layer containing therein a luminescent active material and nanoparticles with a localized surface plasmon resonance effect; a second electrode located on a side of the light emitting layer away from the first electrode. In the organic light emitting device, the nanoparticles having a localized surface plasmon resonance effect are arranged in the light emitting layer, and the nanoparticles are used to promote the radiative transition of excitons of the luminescent active material, thereby improving the light emitting efficiency.

### CROSS-REFERENCE TO RELATED APPLICATIONS

This application claims the priority of Chinese Patent Application No. 201911226107.7 filed on Dec. 5, 2019 and entitled “ORGANIC LIGHT EMITTING DEVICE AND METHOD OF MANUFACTURING THE SAME, AND DISPLAY APPARATUS”, the disclosures of which are incorporated herein by reference in their entirety.

### FIELD

Embodiments of the present disclosure generally relate to the field of display technology, and particularly to an organic light emitting device, a method of manufacturing the same and a display apparatus.

### BACKGROUND

Organic Light Emitting Diodes (OLED)-based displays have the advantages of autonomous light emission, fast response speed, high contrast, and wide viewing angle compared with passive luminous liquid crystal displays (LCDs), will easily realize flexible display, and are increasingly used in various display apparatus and electronic devices. OLEDs rely on an organic functional layer sandwiched between an anode and a cathode to achieve light emission. The organic functional layers generally include a hole injection layer (HIL), a hole transport layer (HTL), and a light emitting layer (EML), an electron transport layer (ETL), and an electron injection layer (EIL), etc. At present, the methods for forming the functional material layers of the OLED mainly include a vacuum thermal evaporation process and an inkjet printing (IJP) process. The vacuum thermal evaporation process has a higher equipment cost. In contrast, as the inkjet printing process has the advantage of high material utilization, etc., the inkjet printing process has many advantages such as material saving, mild process conditions, and more uniform film formation, and thus is suitable for preparing a large-sized OLED display.

However, the current organic light emitting devices, methods of manufacturing them, and display apparatuses, especially organic light emitting devices based on inkjet printing processes, still need to be improved.

### SUMMARY

In one aspect of the present disclosure, there is provided an organic light emitting device including:

a first electrode

a second electrode; and

a light emitting layer located between the first electrode and the second electrode;

wherein, a thickness of the light emitting layer is greater than 40 nm, and the light emitting layer contains therein a luminescent active material and nanoparticles configured to generate a localized surface plasmon resonance effect.

According to an embodiment of the present disclosure, a difference between a wavelength of an absorption peak of the localized surface plasmon resonance effect of the nanoparticles and a wavelength of an emission peak of light emitted by the luminescent active material is ranged from −10 nm to +10 nm.

According to an embodiment of the present disclosure, the nanoparticles each have a metal core and an isolation layer covering outside of the metal core. Thereby, it is possible to prevent excitons of the luminescent active material from directly contacting the metal nucleus to cause quenching of the excitons.

According to an embodiment of the present disclosure, a material for forming the metal core includes at least one of Au, Ag, Al, Zn, Cu, Cr, Cd, and Pt.

According to an embodiment of the present disclosure, a size of the metal core is ranged from 0.1 nm to 100 nm.

According to an embodiment of the present disclosure, a thickness of the isolation layer is ranged from 3 nm to 45 nm.

According to an embodiment of the present disclosure, the thickness of the isolation layer is ranged from 5 nm to 10 nm.

According to an embodiment of the present disclosure, the isolation layer is formed of silicon dioxide.

According to an embodiment of the present disclosure, the organic light emitting device further includes: a hole injection layer located on a side of the first electrode facing towards the light emitting layer; a hole transport layer located between the hole injection layer and the light emitting layer; an electron transport layer located on a side of the light emitting layer facing away from the hole transport layer; and an electron injection layer located between the second electrode and the light emitting layer.

According to an embodiment of the present disclosure, the luminescent active material of the light emitting layer is an organic luminescent active material.

According to an embodiment of the present disclosure, the organic light emitting device further includes a substrate on which the first electrode or the second electrode is arranged.

In another aspect of the present disclosure, there is provided a display apparatus, including a display backplane; wherein the display backplane comprises the organic light emitting device as claimed in claim 1 for providing a light source to the display apparatus; and a packaging structure for mounting the organic light emitting device in the display backplane.

In another aspect of the present disclosure, there is provided a method of manufacturing the organic light emitting device described above. The method includes: forming a first electrode; forming the light emitting layer on a side of the first electrode, the light emitting layer including the luminescent active material and the nanoparticles; and disposing the second electrode on a side of the light emitting layer facing away from the first electrode. Thereby, the organic light emitting device described above can be easily obtained.

According to an embodiment of the present disclosure, the step of forming the light emitting layer comprises: preparing the nanoparticles; and adding the nanoparticles into a dispersion solvent, and mixing the dispersion solution containing the nanoparticles with the luminescent active material to form a light emitting layer solution. This makes it possible to easily mix the luminescent active material with the nanoparticles.

According to an embodiment of the present disclosure, the step of preparing the nanoparticles includes a step of forming the metal core and a step of forming the isolation layer covering the metal core.

According to an embodiment of the present disclosure, the material for forming the metal core comprises at least one of Au, Ag, Al, Zn, Cu, Cr, Cd, or Pt; the step of forming the isolation layer covering the metal core includes: centrifuging the metal core and re-dissolving the metal core in a hydrolysis solution to form a metal core micelle, adding an organosilicon source into the hydrolysis solution to hydrolyze the organosilicon source at the metal core micelle so as to form a silicon dioxide isolation layer outside the metal core, and wherein the hydrolysis solution comprises a cetyltrimethyl ammonium bromide and the organosilicon source comprises a tetraethoxysilane.

According to an embodiment of the present disclosure, the light emitting layer is formed by spinning coating or printing a light emitting layer solution.

The display apparatus may have all the features and advantages of the organic light emitting device described above, and details thereof are not described herein again. In general, the display apparatus has at least advantage of high light emitting efficiency.

### BRIEF DESCRIPTION OF THE DRAWINGS

FIG. 1 is a schematic structural diagram of an organic light emitting device according to an embodiment of the present disclosure;

FIG. 2 is a schematic structural diagram of a nanoparticle according to an embodiment of the present disclosure;

FIG. 3 is a schematic structural diagram of an organic light emitting device according to an embodiment of the present disclosure;

FIG. 4 is a schematic diagram showing a principle of generating a localized surface plasmon oscillation effect according to an embodiment of the present disclosure;

FIG. 5 is a schematic flowchart of a method for preparing an organic light emitting device according to an embodiment of the present disclosure;

FIG. 6 is a schematic structural diagram of a display apparatus according to an embodiment of the present disclosure;

FIG. 7 is a schematic structural diagram of an organic light emitting device according to an embodiment of the present disclosure; and

FIG. 8 is a schematic structural diagram of a display apparatus according to an embodiment of the present disclosure.

### DETAILED DESCRIPTION

Hereinafter, embodiments of the present disclosure will be described in detail. Examples of the embodiments are shown in the accompanying drawings, in which the same or similar reference numerals represent the same or similar elements or elements having the same or similar functions throughout. The embodiments described below with reference to the drawings are exemplary and are only used to explain the present disclosure, and should not be construed as limiting the present disclosure.

In one aspect of the present disclosure, the present disclosure provides an organic light emitting device. The organic light emitting device includes a first electrode 100, a light emitting layer 200, and a second electrode 300. The light emitting layer 200 is located between the first electrode 100 and the second electrode 300. A thickness of the light emitting layer is greater than 40 nm. The light emitting layer contains therein a luminescent active material and nanoparticles 210 configured to generate a localized surface plasmon resonance effect. The organic light emitting device is provided by disposing nanoparticles having a localized surface plasmon resonance effect in a light emitting layer, so as to use the nanoparticles to further promote the radiative transition of excitons of the luminescent active material, thereby improving the light emitting efficiency of the light emitting layer. The light emitting layer is allowed to have an increased thickness such that the amount of light can be increased, and thus difficulty of preparing the light emitting layer can be reduced and a stability of the light emitting layer is improved.

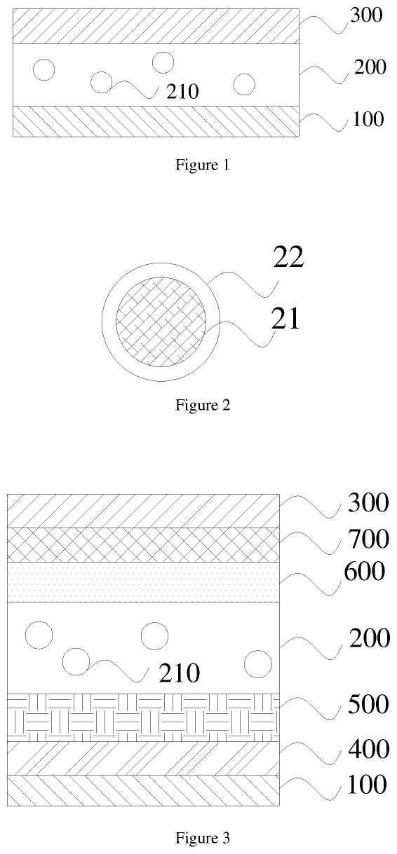

FIG. 1 illustrates an organic light emitting device according to an embodiment of the present disclosure, including a first electrode 100, a light emitting layer 200 located on a side of the first electrode 100, and a second electrode 300 on a side of the light emitting layer 200 facing away from the first electrode 100. A thickness of the light emitting layer is greater than 40 nm, and the light emitting layer contains therein a luminescent active material and nanoparticles 210 configured to generate a localized surface plasmon resonance effect. In this embodiment, the first electrode 100, the light emitting layer 200, and the second electrode 300 each have a planar structure, and the “side” herein may refer to a side face.

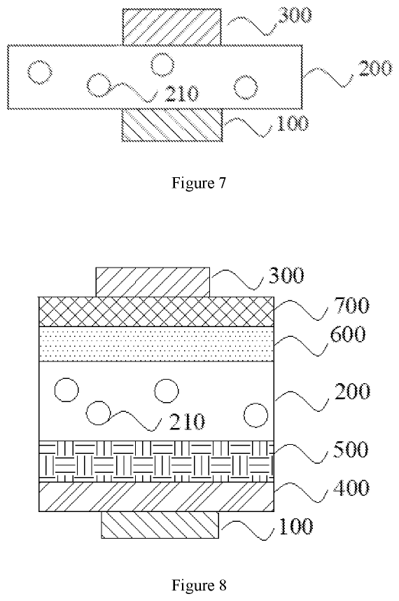

It should be noted that, although the first electrode 100, the light emitting layer 200, and the second electrode 300 illustrated in the embodiment shown in FIG. 1 each have a planar structure and have a same area (the area in a horizontal plane as shown in FIG. 1), in other embodiments, the first electrode 100 and the second electrode 300 may have a smaller area (area extending within a plane perpendicular to a thickness direction) than the light emitting layer 200. For example, FIG. 7 illustrates an embodiment of the organic light emitting device, in which the first electrode 100 and the second electrode 300 are located on opposite sides of the light emitting layer 200, respectively, and the areas of the first electrode 100 and the second electrode 300 are less than the area of the light emitting layer 200. It can be considered that the first electrode 100 and the second electrode 300 are conductive pads respectively disposed on the opposite sides of the light emitting layer 200 and cover a part of the opposite sides of the light emitting layer 200. Positions of the first electrode 100 and the second electrode 300 on the corresponding sides of the light emitting layer 200 may be set as required, for example, at the center; however, they may also be set at other positions that do not hinder light emission.

For easy understanding, the following briefly describes the principle that the organic light emitting device can achieve the above beneficial effects:

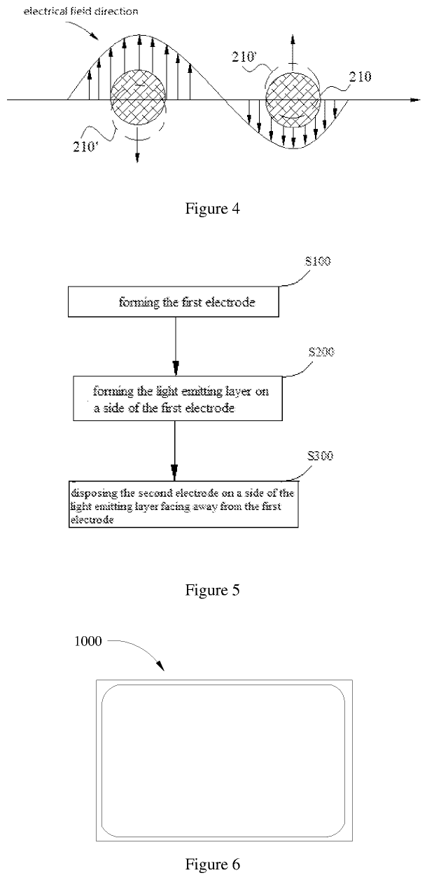

Metal nanoparticles have attracted widespread attention in properties enhancement of OLED devices due to their unique optoelectronic properties. For example, metal nanoparticles can generate a localized surface plasmon resonance (LSPR) effect, thereby improving a light emitting efficiency of an organic light emitting device. Referring to FIG. 4, the basic principle is roughly as follows: when light is irradiated onto a nano-metal spheres, such as a nanoparticle 210 described in the present disclosure, an oscillating electric field causes a coherent oscillation of conduction electrons. If a frequency of an incident light matches a natural oscillation frequency of the electrons inside the nanoparticle, an oscillating electromagnetic field of the incident light will drive free electrons of the surface of the metal nanoparticle to move and in turn cause a surface electron cloud (as denoted by 210′ shown by the dotted line in the Figure) to deviate from the nucleus (corresponding to the nanoparticle 210 shown in FIG. 4). When the surface electron cloud 210′ is shifted relative to the atomic nucleus, a coulomb attraction between the electron and the nucleus causes a restoring force, resulting in an oscillation of the surface electron cloud 210′ with respect to a normal lattice of metal particles and in turn generating a localized surface plasmon. When the oscillation frequency of the free electrons is consistent with the frequency of the incident light, resonance will occur, so that a collective oscillation of the electrons on the surface of the nanoparticle is greatly enhanced, forming a localized surface plasmon resonance. In the organic light emitting device, the exciton recombined in the light emitting layer will return to a ground state by means of radiative transitions and non-radiative transitions, in which the radiative transitions in the light emitting layer is reflected by lighting. On the other hand, with the near-field enhancement of localized surface plasmon excitation, the localized surface plasmon resonance effect will promote the radiative transition rate of excitons, thereby increasing the quantum yield of the device. Further, the light emitting efficiency of the organic light emitting device is improved.

It is found by the inventors that an approach of providing nanoparticles with a localized surface plasmon resonance effect in a light emitting layer is particularly suitable for an organic light emitting device with a rather thick light emitting layer. Specifically, since the plasmon resonance of the nanoparticle is formed by an oscillation of the electrons on an outer surface of the core, the resonance effect is localized to a certain region where the nanoparticle is located. In a case where the light emitting layer is thicker, if the nanoparticles are placed in a position other than the light emitting layer, for example, in other layers/structures adjacent to the light emitting layer, the radiative transition of the exciton will not be promoted by the nanoparticles due to a too large distance between the luminescent active material and the nanoparticles. In particular, unlike organic light emitting structures prepared by evaporation methods, a light emitting layer in a solution-type organic light emitting device structure suitable for the inkjet printing process generally has a rather large thickness for taking into account a function of an electron transport layer at the same time. Depending on color of a light it emits, the thickness of the light emitting layer is usually between 40 nm-90 nm, and may even be greater than 100 nm. Therefore, the distance between the luminescent active material and the nanoparticles goes beyond a scope of action of the localized surface plasmon resonance in a case where a metal nanoparticle layer is provided adjacent to the light emitting layer. Thus, a design where a separated layer containing nanoparticles is provided is not applicable.

According to an embodiment of the present disclosure, a difference between a wavelength of an absorption peak of the localized surface plasmon resonance effect of a nanoparticle and a wavelength of an emission peak of the luminescent active material may be ranged from −10 nm to +10 nm. In this case, the nanoparticle can be used to improve the radiative transition of the exciton in the luminescent active material. According to the embodiment of the present disclosure, the nanoparticles is not particularly limited to have a specific structure, as long as a suitable distance from the exciton in the luminescent active material can avoid the exciton from transferring its energy to the nanoparticles in manner of the non-radiative transitions and the radiation transition of the exciton in the luminescent active material can be promoted. Specifically, referring to FIG. 2, the nanoparticle may have a metal core 21 and an isolation layer 22 covering or wrapped around the metal core 21. The isolation layer 22 may be formed by an insulating material, for example, may be formed by silicon dioxide. Thereby, the light emitting efficiency of the organic light emitting device can be further improved. That is, the nanoparticle may have a core-shell structure. This can prevent the exciton of the luminescent active material from directly contacting the electron cloud, which can cause quenching of the exciton.

According to the embodiment of the present disclosure, the material for forming the metal core is not particularly limited herein, and may include at least one of, for example, Au, Ag, Al, Zn, Cu, Cr, Cd, or Pt. Thereby, the light emitting efficiency of the organic light emitting device can be further improved. Specifically, metal cores formed by Au, Ag, Cu can enhance a luminescence intensity of luminescent molecules in the visible-near and infrared regions, metal cores formed by Al can enhance the luminescence intensity of luminescent molecules in the ultraviolet and blue regions, and metal cores formed by Zn can enhance the luminescence intensity of luminescent molecules in the blue and red regions. The metal core formed by Cr can enhance the luminescence intensity of the luminescent molecules in the light emitting region of 510-620 nm, and the metal core formed by Pt can enhance the luminescence intensity of the luminescent molecules in the green and red regions. Therefore, the light emitting efficiency of the organic light emitting device can be further improved, and an appropriate material can be selected to form a metal core according to the specific requirements of the organic light emitting device for light emission. According to the embodiments of the present disclosure, the particle size of the metal core is not particularly limited, and those skilled in the art can adjust the effect of the localized surface plasmon resonance of the nanoparticles by jointly taking account to the specific chemical composition, surface morphology, and particle size of the metal core. For example, specifically, the particle size of the metal core may be in a range of 0.1-100 nm. Thereby, the light emitting efficiency of the organic light emitting device can be further improved.

According to the embodiment of the present disclosure, a thickness of the isolation layer is not particularly limited, as long as the luminescent active material can be prevented from being quenched, and as long as the localized surface plasmon resonance of the metal core will not be blocked due to the isolation layer being too thick. For example, the thickness of the isolation layer may be 3 nm˜45 nm, and more specifically, 5 n˜10 nm, thereby the light emitting efficiency of the organic light emitting device can be further improved. This can avoid an increase in non-radiative transition rates and quenching of the excitons which are otherwise caused due to the excitons transferring energy to the nanoparticles through non-radiative transitions when the nanoparticles come into direct contact with the luminescent active material.

According to the embodiment of the present disclosure, the organic light emitting device may further include other stacked structures. For example, referring to FIG. 3, the organic light emitting device may further include a hole injection layer 400 and a hole transport layer 500, which are located between the first electrode 100 and the light emitting layer 200. Similarly, there may be an electron transport layer 600 and an electron injection layer 700 between the second electrode 300 and the light emitting layer 200. Thereby, the light emitting efficiency of the organic light emitting device can be further improved. In this case, the first electrode may be an anode, and the second electrode may be a cathode.

It should be particularly noted here that the relative positions of the hole injection layer 400, the hole transport layer 500, the electron transport layer 600, and the electron injection layer 700 described above with respect to the first electrode and the second electrode may be relative positions relationship commonly used in the art, that is, one of the first electrode and the second electrode is the anode and the other is the cathode, the hole injection layer and the hole transport layer are located on a side of the anode, and the electron injection layer and the electron transport layer are located on a side of the cathode. As for the positions described above, it is only shown herein the case where the first electrode is an anode and the second electrode is a cathode. When the first electrode is a cathode and the second electrode is an anode, the positions of the hole injection layer 400, the hole transport layer 500, the electron transport layer 600 and the electron injection layer 700 should also be changed accordingly. Similarly, the organic light emitting device herein may also have other common structures of an organic light emitting devices, such as a substrate (not shown).

According to an embodiment of the present disclosure, as shown in FIG. 8, the embodiment of FIG. 8 is similar to the embodiment of FIG. 3, except that the first electrode 100 and the second electrode 300 are different from those shown in FIG. 3. In the embodiment shown in FIG. 8, areas of the first electrode 100 and the second electrode 300 are relatively small, and the first electrode 100 and the second electrode 300 are respectively disposed on the hole injection layer 400 and the electron injection layer 700 in such a way that they are located within regions with smaller area than orthographic projections of the hole injection layer 400 and the electron injection layer 700, and are electrically connected to the hole injection layer 400 and the electron injection layer 700 respectively. The positions of the first electrode 100 and the second electrode 300 on the hole injection layer 400 and the electron injection layer 700 respectively may be set as required, for example, at the center positions of the hole injection layer 400 and the electron injection layer 700; however, they may also be set at such positions that they do not hinder light emission. Reducing the areas of the first electrode 100 and the second electrode 300 has little effect on the light emitting performance of the light emitting device, and for a surface light emitting device, the blocking or weakening effect by the electrode on light will be reduced.

In another aspect of the present disclosure, the present disclosure proposes a method of manufacturing the organic light emitting device described above.

Referring to FIG. 5, the method includes:

step S100 of forming the first electrode;

According to an embodiment of the present disclosure, in this step, the first electrode may be formed on a substrate by using a process including, but not limited to, a sputtering deposition. The first electrode may be formed of a material commonly used for forming an anode or a cathode in an organic light emitting diode.

step S200 of forming the light emitting layer on a side of the first electrode facing away from the substrate;

According to an embodiment of the present disclosure, the light emitting layer is formed in this step. Specifically, the light emitting layer may include the luminescent active material and the nanoparticles. The material, thickness, and specific structure of the nanoparticles of the light emitting layer have been described in detail above, and are not repeated here. According to an embodiment of the present disclosure, the step of forming the light emitting layer may specifically include a step of preparing nanoparticles, and a step of mixing the nanoparticles with the luminescent active material to form the light emitting layer. Specifically, the prepared nanoparticles may be added into a dispersion solvent, and the dispersion solution containing the nanoparticles may be mixed with the luminescent active material to form a light emitting layer solution. The light emitting layer may be formed by spin-coating or printing the light emitting layer solution to form a film. Thereby, the light emitting layer can be formed easily.

According to an embodiment of the present disclosure, the step of preparing the nanoparticles may specifically include a step of forming the metal core, and a step of forming an isolation layer covering or wrapped around the metal core. The steps of forming the metal core and preparing the isolation layer covering or wrapped around the metal core may adopt processes or operations commonly used in the art. For example, specifically, the metal core may be formed first. For example, the material, particle size, and surface morphology of the metal core may be determined according to the specific requirements for light emission of the organic light emitting device. For example, the material for forming the metal core may include at least one of Au, Ag, Al, Zn, Cu, Cr, Cd, or Pt. Specifically, the metal core can be formed by using a solution process, and then a solution containing the metal core is subjected to centrifugation treatment and centrifugal precipitate is collected. The centrifugal precipitate is re-dissolved in a hydrolysis solution to form metal core micelles. Subsequently, an organosilicon source is added to the hydrolysis solution to hydrolyze the organosilicon source and form a silicon dioxide isolating layer covering or wrapping around the metal core. Specifically, the hydrolysis solution may include cetyltrimethyl ammonium bromide (CTAB), dodecyl trimethylammonium bromide (DTAB), or tetradecyl trimethylammonium bromide (TTAB). The organosilicon source may include ethyl orthosilicate, methyl triethoxysilane, or methyl trimethoxysilane. In this step, a thickness of the silicon dioxide isolation layer formed can be controlled by adjusting a concentration of the hydrolysis solution, for example, a concentration of CTAB. The hydrolysis solution may be a solution formed by dissolving CTAB in a good solvent for CTAB. The good solvent for CTAB may be ethanol or acetone. The larger the concentration of CTAB in the hydrolysis solution is, the more favorable it is to form a thinner isolation layer. According to a specific embodiment of the present disclosure, the concentration of CTAB may be ranged from 20 μmol/L to 1200 μmol/L.

Step S300 of providing the second electrode on a side of the light emitting layer facing away from the first electrode is included.

According to an embodiment of the present disclosure, a second electrode may be provided on the side of the light emitting layer facing away from the first electrode in this step. Thereby, the organic light emitting device described above can be easily obtained.

It is understood by those skilled in the art that, when the organic light emitting device has components such as a hole injection layer, a hole transport layer, a hole injection layer, and a hole transport layer, the method may further include processes of forming the above components. Those skilled in the art may select the commonly used materials and processes to form the above layers according to the specific light emission requirements of the organic light emitting device.

In yet another aspect of the present disclosure, the present disclosure provides a display apparatus. Referring to FIG. 6, according to an embodiment of the present disclosure, the display apparatus 1000 includes a display backplane (not shown in the Figure), which has the aforementioned organic light emitting device configured for providing a light source for the display apparatus. The display backplane may further include a packaging structure, which is configured to mount the organic light emitting device in the display backplane. Therefore, the display apparatus may have all the features and advantages of the organic light emitting device described above, and details thereof are not described repeatedly herein again. In general, the display apparatus has at least one of the advantages such as the high light emitting efficiency.

The following describes the present disclosure through specific examples. Those skilled in the art can understand that the following specific examples are only for the purpose of illustration, and do not tend to limit the scope of the present disclosure in any way. In addition, in the following examples, unless otherwise specified, the materials and equipment used are commercially available. If specific processing conditions and processing methods are not explicitly described in the following embodiments, conditions and methods known in the art may be used for processing.

### Example 1

1. Preparation of Nanoparticles

Spherical Au metal cores were prepared and, after centrifugation, re-dissolved in 2 mL cetyltrimethyl ammonium bromide (CTAB) solution with a concentration of 500 μmol/L. Then, tetraethyl orthosilicate (TEOS) was added into the solution to form silicon dioxide covering or wrapping around the surface of the Au metal core, forming an isolation layer with a thickness of 10 nm outside of the metal core.

2. Preparation of Mixed Solution for Light Emitting Layer

The nanoparticles prepared in step 1 were centrifuged 3 times with ethanol, and dried at 90° C. Then, a solvent including toluene was added to disperse the nanoparticles, and then the nanoparticles were mixed with the light emitting layer material and stirred uniformly.

3. Preparation of Organic Light Emitting Devices

An anode was formed on the substrate, and then a hole injection layer and a hole transport layer were formed. A light emitting layer was formed by printing (IJP) with the mixed solution for the light emitting layer prepared in step 2, and an electron transport layer, an electron injection layer and a cathode are subsequently formed. The thickness of the light emitting layer formed was 80 nm.

### Example 2

The remaining steps in example 2 are the same as those in Example 1, except that an 800 μmol/L cetyltrimethyl ammonium bromide (CTAB) solution was used to prepare the nanoparticles, and the thickness of the isolation layer was 30 nm.

### Example 3

The remaining steps in example 3 are the same as those in Example 1, except that the metal cores are spherical Al metal cores.

### Example 4

The remaining steps in example 4 are the same as those in Example 1, except that the metal cores are spherical Zn metal cores.

### Example 5

The remaining steps in example 5 are the same as those in Example 1, except that the metal cores are spherical Pt metal cores.

### Comparative Example 1

The remaining steps in this Example are the same as those in Example 1, except that no nanoparticle is added into the light emitting layer solution.

### Comparative Example 2

The remaining steps in this Example are the same as those in Example 1, except that a 1300 μmol/L cetyltrimethyl ammonium bromide (CTAB) solution was used to prepare the nanoparticles, and the thickness of the isolation layer was 50 nm.

### Comparative Example 3

The remaining steps in this Example are the same as those in Example 1, except that a 10 μmol/L cetyltrimethyl ammonium bromide (CTAB) solution is used to prepare the nanoparticles, and the thickness of the isolation layer is 2 nm.

### Comparative Example 4

The remaining steps in this Example are the same as those in Example 1, except that no nanoparticle is added into the light emitting layer solution and a light emitting layer is formed with a thickness of 80 nm, and the nanoparticles prepared in above step are used to form a separated localized surface plasmon resonance adjustment layer adjacent to the light emitting layer.

Characteristics including voltage, efficiency, and color of the organic light emitting devices obtained in Examples 1-5 and Comparative Examples 1-4 were tested. A system composed of PR680 and Keithley-2400 was used together with a computer for simultaneous measurement. It is set that a starting current density is 1 mA/cm², a termination current density is 25 mA/cm², and a current density step is 3 mA/cm² for continuous testing. Corresponding voltage (V), efficiency (Expressed as current efficiency cd/A) and a color point (CIEx and CIEy) of the device are tested when the current density (J) of 10 mA/cm² is selected. In the examples, examples 1-5 obtain higher current efficiencies than the comparative examples, that is, have better luminous efficiency. At the same time, the color points of the devices of Examples 1 and 2 are similar to that of Comparative Example 1, that is, the color of the emitting light is not affected after the nanoparticles are added to the light emitting layer. By comparison, the luminous efficiency of Example 1 is slightly higher than that of Example 2, but the current efficiencies of Examples 1 and 3-5 are similar. Comparative Example 1 and Comparative Example 2 obtain low luminous efficiencies as the radiative transition of excitons cannot be enhanced by the localized surface plasmon resonance effect (it is basically unable to enhance due to too large distance). In Comparative Example 3, because the thickness of the isolation layer is too small, the exciton of the luminescent active material directly contacts the electron cloud causing quenching of the exciton, and therefore, the luminous efficiency is greatly reduced and the current efficiency is only 5 cd/A.

TABLE 1

| | | | Device | | |
|---|---|---|---|---|---|
| | Voltage | J | efficiency | | |
| Order number | (V) | (mA/cm2) | cd/A | CIEx | CIEy |
| Comparative | 7.5 | 10 | 16 | 0.675 | 0.325 |
| Example 1 | | | | | |
| Comparative | 7.8 | 10 | 15.5 | 0.674 | 0.326 |
| Example 2 | | | | | |
| Comparative | 7.7 | 10 | 5 | 0.679 | 0.327 |
| Example 3 | | | | | |
| Example 1 | 7.8 | 10 | 19 | 0.680 | 0.327 |

In the description of the present disclosure, the orientations or positional relationships indicated by the terms “up”, “down”, and the like are based on the orientations or positional relationships shown in the accompanying drawings, and are only for the convenience of describing the disclosure but do not tend to require the disclosure to be configured and operated at particular orientations, and are therefore not to be understood as limiting the present disclosure.

In the description of this specification, the description with reference to the terms “an embodiment”, “another embodiment”, etc. mean that a specific feature, structure, material, or characteristic described in connection with the embodiment is included in at least one embodiment of the present disclosure. In this specification, the schematic expressions of the above terms are not necessarily directed to the same embodiment or example. Moreover, the particular features, structures, materials, or characteristics described may be combined in any suitable manner in any one or more embodiments or examples. In addition, without any contradiction, those skilled in the art may combine different embodiments or examples and features of the different embodiments or examples described in this specification. In addition, it should be noted that in this specification, the terms “first” and “second” are used for description purposes only, and cannot be understood as indicating or implying relative importance or implicitly indicating the number of technical features indicated.

Although the embodiments of the present disclosure have been shown and described above, it can be understood that the above embodiments are exemplary and should not be construed as limitations on the present disclosure. Those skilled in the art can make changes, modifications, substitutions, and variations on the above embodiments within the scope of the present disclosure.

1. An organic light emitting device, comprising:
a first electrode
a second electrode; and
a light emitting layer located between the first electrode and the second electrode;
wherein, a thickness of the light emitting layer is greater than 40 nm, and the light emitting layer contains therein a luminescent active material and nanoparticles configured to generate a localized surface plasmon resonance effect.

2. The organic light emitting device as claimed in claim 1, wherein a difference between a wavelength of an absorption peak of the localized surface plasmon resonance effect of the nanoparticles and a wavelength of an emission peak of light emitted by the luminescent active material is ranged from −10 nm to +10 nm.

3. The organic light emitting device as claimed in claim 2, wherein the nanoparticles each have a metal core and an isolation layer covering outside of the metal core.

4. The organic light emitting device as claimed in claim 3, wherein a material for forming the metal core comprises at least one of Au, Ag, Al, Zn, Cu, Cr, Cd, or Pt.

5. The organic light emitting device as claimed in claim 3, wherein a size of the metal core is ranged from 0.1 nm to 100 nm.

6. The organic light emitting device as claimed in claim 3, wherein a thickness of the isolation layer is ranged from 3 nm to 45 nm.

7. The organic light emitting device as claimed in claim 6, wherein the thickness of the isolation layer is ranged from 5 nm to 10 nm.

8. The organic light emitting device as claimed in claim 3, wherein the isolation layer is formed of silicon dioxide.

9. The organic light emitting device as claimed in claim 1, further comprising:
a hole injection layer located on a side of the first electrode facing towards the light emitting layer;
a hole transport layer located between the hole injection layer and the light emitting layer;
an electron transport layer located on a side of the light emitting layer facing away from the hole transport layer; and
an electron injection layer located between the second electrode and the light emitting layer.

10. The organic light emitting device as claimed in claim 1, wherein the luminescent active material of the light emitting layer is an organic luminescent active material.

11. The organic light emitting device as claimed in claim 1, further comprising a substrate on which the first electrode or the second electrode is arranged.

12. A display apparatus, comprising:
a display backplane;
wherein the display backplane comprises the organic light emitting device as claimed in claim 1 for providing a light source to the display apparatus; and a packaging structure for mounting the organic light emitting device in the display backplane.

13. A method of manufacturing the organic light emitting device as claimed in claim 1, wherein the method comprises:
forming the first electrode;
forming the light emitting layer on a side of the first electrode, the light emitting layer including the luminescent active material and the nanoparticles; and
disposing the second electrode on a side of the light emitting layer facing away from the first electrode.

14. The method as claimed in claim 13, wherein the step of forming the light emitting layer comprises:
preparing the nanoparticles; and
adding the nanoparticles into a dispersion solvent, and mixing the dispersion solution containing the nanoparticles with the luminescent active material to form a light emitting layer solution.

15. The method of claim 13, wherein the step of preparing the nanoparticles comprises:
a step of forming the metal core and a step of forming the isolation layer covering the metal core.

16. The method as claimed in claim 15, wherein the material for forming the metal core comprises at least one of Au, Ag, Al, Zn, Cu, Cr, Cd, or Pt;
the step of forming the isolation layer covering the metal core includes: centrifuging the metal core and re-dissolving the metal core in a hydrolysis solution to form a metal core micelle, adding an organosilicon source into the hydrolysis solution to hydrolyze the organosilicon source at the metal core micelle so as to form a silicon dioxide isolation layer outside the metal core, and
wherein the hydrolysis solution comprises a cetyltrimethyl ammonium bromide and the organosilicon source comprises a tetraethoxysilane.

17. The method as claimed in claim 13, wherein the light emitting layer is formed by spinning coating or printing a light emitting layer solution.
